(19) United States
(12) Patent Application Publication
(10) Pub. No.: US 2025/0063725 A1
(43) Pub. Date: Feb. 20, 2025

(54) SEMICONDUCTOR DEVICE INCLUDING BIT LINE

(71) Applicant: Samsung Electronics Co., Ltd., Suwon-si (KR)

(72) Inventors: Jongmin KIM, Suwon-si (KR); Seungbo KO, Suwon-si (KR); Donghyuk AHN, Suwon-si (KR); Minyoung LEE, Suwon-si (KR)

(73) Assignee: Samsung Electronics Co., Ltd., Suwon-si (KR)

(21) Appl. No.: 18/656,933

(22) Filed: May 7, 2024

(30) Foreign Application Priority Data
Aug. 17, 2023 (KR) 10-2023-0107621

(51) Int. Cl. H10B 12/00; H01L 29/06; H01L 29/423; H01L 29/66

(52) U.S. Cl. CPC H10B 12/482; H01L 29/0649; H01L 29/4236; H01L 29/66553; H10B 12/34; H10B 12/50

(57) ABSTRACT

A semiconductor device may include first and second bit lines that each include a line portion, a connection portion extending from the line portion into a first extension region, and a pad portion extending from the connection portion in the first extension region; and a third bit line between the line portions of the first and second bit lines in a memory cell array region and the first extension region. A first end portion of the third bit line may be in the first extension region. The pad portions of the first and second bit lines each may be wider than the line portions of the first and second bit lines. A minimum distance between the pad portions of the first and second bit lines may be less than a minimum distance between the line portion of the first bit line and the third bit line.

CROSS-REFERENCE TO RELATED APPLICATION(S)

This application claims benefit of priority to Korean Patent Application No. 10-2023-0107621 filed on Aug. 17, 2023 in the Korean Intellectual Property Office, the disclosure of which is incorporated herein by reference in its entirety.

### BACKGROUND

Example embodiments relate to a semiconductor device and a method of manufacturing the same.

Research has been conducted to reduce sizes of elements included in a semiconductor device and to improve performance thereof. For example, in DRAM, research has been conducted to reliably and stably form elements having a reduced size.

### SUMMARY

Example embodiments provide a semiconductor device having an increased degree of integration.

Example embodiments provide a semiconductor device having improved reliability.

Example embodiments provide a method of manufacturing a semiconductor device having an increased degree of integration and/or improved reliability.

According to example embodiments, a semiconductor device may include a structure including a first extension region and a memory cell array region, the first extension region being adjacent to the memory cell array region; a first bit line including a first line portion extending into the first extension region while crossing the memory cell array region in a first direction, a first connection portion extending from the first line portion in the first extension region, and a first pad portion extending from the first connection portion in the first extension region; a second bit line including a second line portion extending into the first extension region while crossing the memory cell array region in the first direction, a second connection portion extending from the first line portion in the first extension region, and a second pad portion extending from the second connection portion in the first extension region; and a third bit line between the first line portion and the second line portion in the memory cell array region and the first extension region, the third bit line including a first end portion in the first extension region. A width of the first pad portion in a second direction and a width of the second pad portion in the second direction each may be greater than a width of the first line portion in the second direction and a width of second line portion in the second direction. The second direction may be perpendicular to the first direction. A minimum distance between the first pad portion and the second pad portion may be less than a minimum distance between the first line portion and the third bit line.

According to example embodiments, a semiconductor device may include a structure including a first extension region and a memory cell array region, the first extension region being adjacent to the memory cell array region; a first bit line including a first line portion extending into the first extension region while crossing the memory cell array region in a first direction, a first connection portion extending from the first line portion in the first extension region, and a first pad portion extending from the first connection portion in the first extension region; a second bit line including a second line portion extending into the first extension region while crossing the memory cell array region in the first direction, a second connection portion extending from the first line portion in the first extension region, and a second pad portion extending from the second connection portion in the first extension region; a third bit line between the first line portion and the second line portion in the memory cell array region and the first extension region, the third bit line including a first end portion in the first extension region; contact plugs including cell contact plugs in the memory cell array region and dummy contact plugs in the first extension region; and an insulating pattern in the first extension region. The insulating pattern may include a first insulating portion between the first pad portion and the second pad portion. The dummy contact plugs may include a first dummy contact plug. At least a portion of the first dummy contact plug may be between the insulating pattern and the first end portion of the third bit line.

According to example embodiments, a semiconductor device may include a structure including a first extension region and a memory cell array region, the first extension region being adjacent to the memory cell array region; a first bit line including a first line portion extending into the first extension region while crossing the memory cell array region in a first direction, a first connection portion extending from the first line portion in the first extension region, and a first pad portion extending from the first connection portion in the first extension region; a second bit line including a second line portion extending into the first extension region while crossing the memory cell array region in the first direction, a second connection portion extending from the first line portion in the first extension region, and a second pad portion extending from the second connection portion in the first extension region; a third bit line between the first line portion and the second line portion in the memory cell array region and the first extension region, the third bit line including a first end portion in the first extension region; contact plugs including cell contact plugs in the memory cell array region and dummy contact plugs in the first extension region; an insulating pattern in the first extension region; and an outer spacer in the memory cell array region and the first extension region. The insulating pattern may include a first insulating portion between the first pad portion and the second pad portion. The outer spacer may include a first outer portion on a side surface of the first line portion facing the third bit line, a second outer portion on a side surface of the second line portion facing the third bit line, and a third outer portion extending from the first outer portion and the second outer portion. The third outer portion may cover a side surface of the insulating pattern positioned in a direction toward the memory cell array region.

### BRIEF DESCRIPTION OF DRAWINGS

The above and other aspects, features, and advantages of inventive concepts will be more clearly understood from the following detailed description, taken in conjunction with the accompanying drawings, in which:

FIGS. 1 to 4E are diagrams illustrating a semiconductor device according to an example embodiment;

FIGS. 5 to 7B are diagrams illustrating a modification of a semiconductor device according to an example embodiment;

FIG. 8 is a plan view of a modification of a semiconductor device according to an example embodiment;

FIG. 9 is a plan view of a modification of a semiconductor device according to an example embodiment;

FIG. 10 is a plan view of a modification of a semiconductor device according to an example embodiment;

FIGS. 11A and 11B are plan views of a modification of a semiconductor device according to an example embodiment;

FIG. 12 is a plan view of a modification of a semiconductor device according to an example embodiment;

FIGS. 13A and 13B are diagrams illustrating a modification of a semiconductor device according to an example embodiment;

FIGS. 14 and 15 are cross-sectional views of a modification of a semiconductor device according to an example embodiment;

FIGS. 16 to 18D are diagrams illustrating an example of a method of manufacturing a semiconductor device according to an example embodiment;

FIG. 19 is a process flowchart illustrating a modification of a method of manufacturing a semiconductor device according to an example embodiment; and

FIG. 20 is a process flowchart illustrating a modification of a method of manufacturing a semiconductor device according to an example embodiment.

### DETAILED DESCRIPTION

Hereinafter, the terms such as “upper portion,” “intermediate portion,” and “lower portion” may be replaced with other terms, for example, “first,” “second,” and “third” to describe elements of the specification. The terms such as “first,” “second,” and “third” may be used to describe different elements, but the elements are not limited by the terms, and a “first element” may be referred to as a “second element.”

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

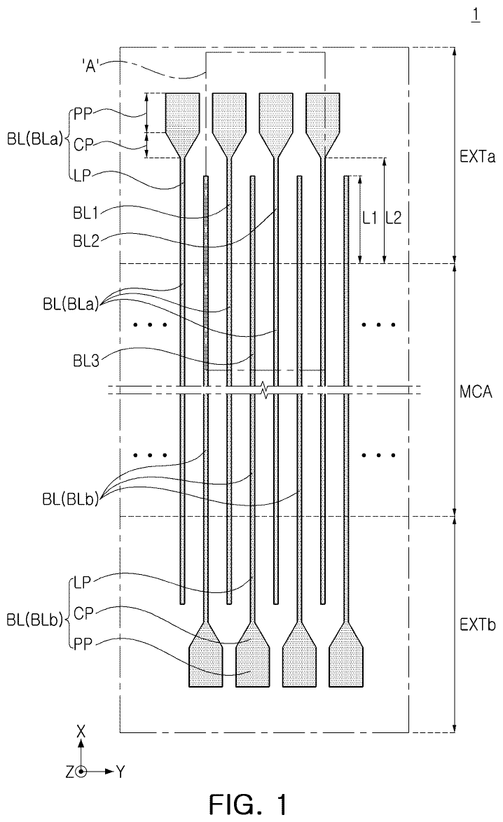

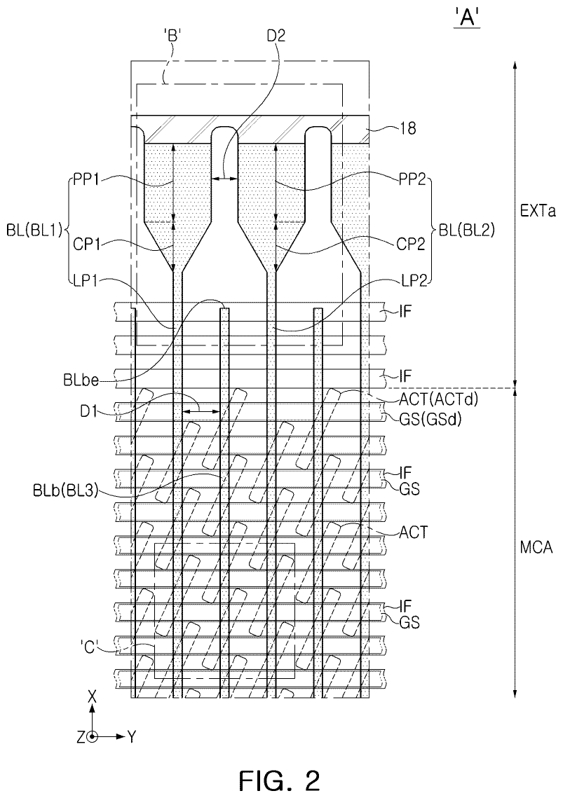

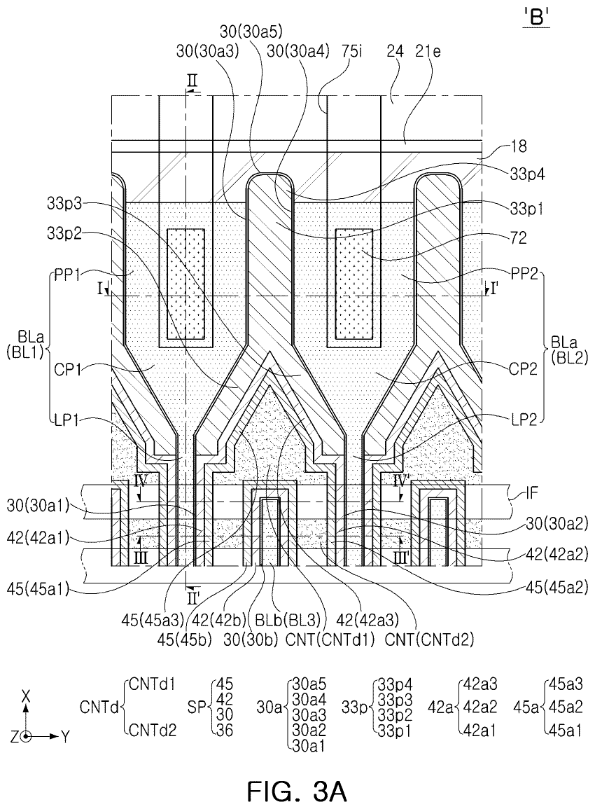

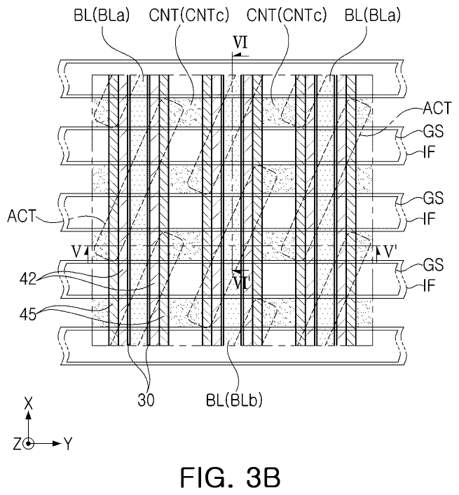

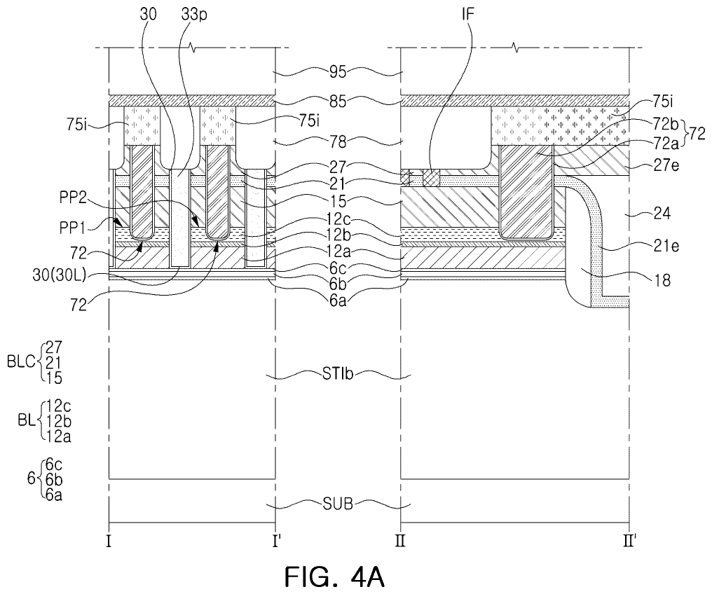

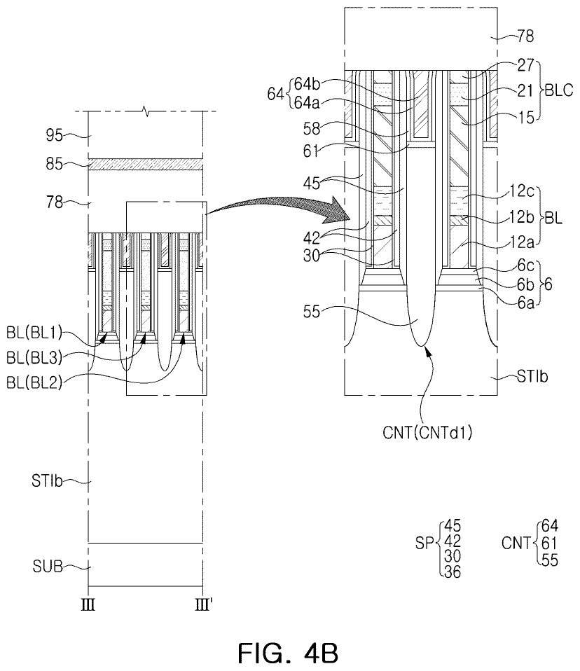

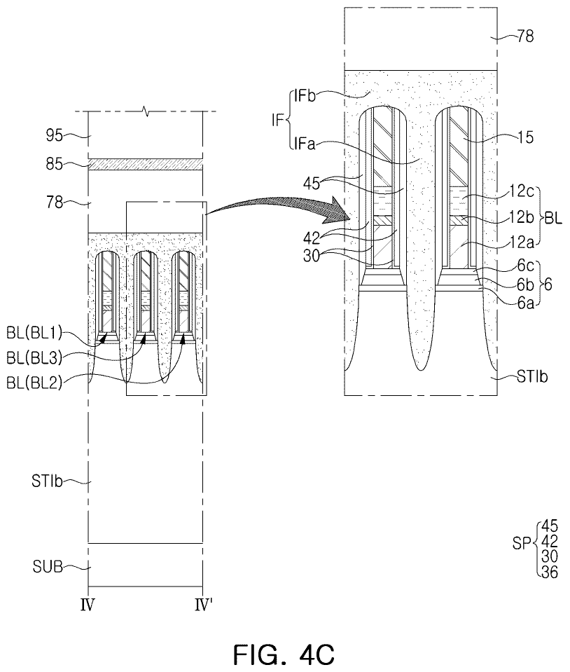

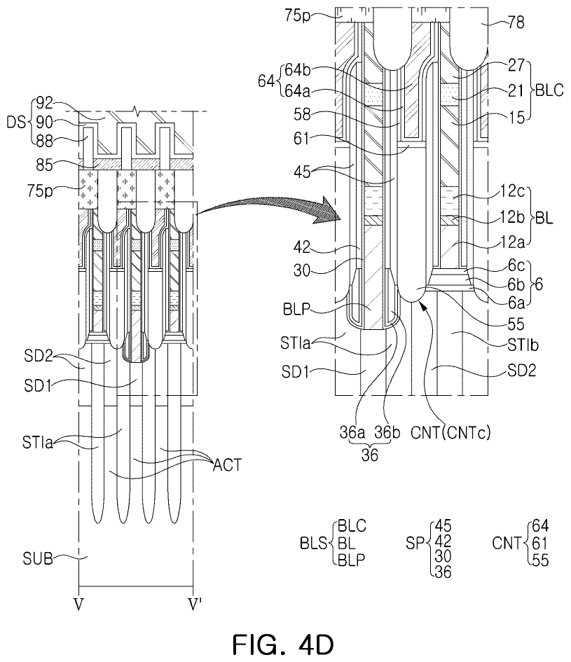

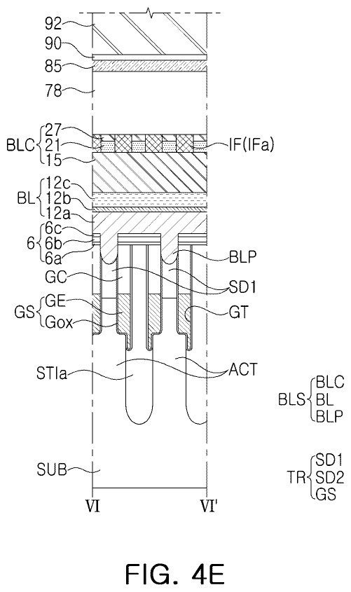

An example of a semiconductor device according to an example embodiment of inventive concepts will be described with reference to FIGS. 1 to 4E. FIGS. 1 to 4E are diagrams illustrating a semiconductor device according to an example embodiment of inventive concepts. FIG. 1 is a plan view of a semiconductor device according to an example embodiment of inventive concepts. FIG. 2 is a partially enlarged view of a region indicated by “A” of FIG. 1. FIG. 3A is a partially enlarged view of a region indicated by “B” of FIG. 2. FIG. 3B is a partially enlarged view of a region indicated by “C” of FIG. 2. FIG. 4A is a cross-sectional view of regions taken along lines I-I′ and II-II′ of FIG. 3A. FIG. 4B is a cross-sectional view of a region taken along line III-III′ of FIG. 3A. FIG. 4C is a cross-sectional view of a region taken along line IV-IV′ of FIG. 3A. FIG. 4D is a cross-sectional view of a region taken along line V-V′ of FIG. 3B. FIG. 4E is a cross-sectional view of a region taken along line VI-VI′ of FIG. 3B.

First, with reference to FIG. 1, among FIGS. 1 to 4E, a planar shape of each of the bit lines BL of a semiconductor device 1 according to an example embodiment will be described.

Referring to FIG. 1, among FIGS. 1 to 4E, the semiconductor device 1 according to an example embodiment may include a memory cell array region MCA, a first extension region EXTa, and a second extension region EXTb. The first extension region EXTa and the second extension region EXTb may be adjacent to the memory cell array region MCA. The memory cell array region MCA may be a region in which memory cells capable of storing data are arranged. The memory cell array region MCA may be disposed between the first extension region EXTa and the second extension region EXTb. The memory cell array region MCA, first extension region EXTa, and the second extension region EXTb may correspond to regions of the substrate SUB of the semiconductor device 1.

The semiconductor device 1 may further include bit lines BL.

The bit lines BL may extend into the first extension region EXTa while crossing the memory cell array region MCA in a first direction X. The bit lines BL may further have portions extending from the memory cell array region MCA to the second extension region EXTb. Accordingly, the bit lines BL may extend into the first and second extension regions EXTa and EXTb while crossing the memory cell array region MCA.

Each of the bit lines BL may include a line portion LP, a connection portion CP extending from the line portion LP in a direction away from the memory cell array region MCA, and a pad portion PP extending from the connection portion CP in a direction away from the memory cell array region MCA.

Each of the line portions LP of the bit lines BL may have a linear shape extending in the first direction X.

In each of the bit lines BL, a width of the pad portion PP in a second direction Y may be greater than a width of the line portion LP in the second direction Y, and the connection portion CP may have a shape having a width gradually increasing in a direction away from the memory cell array region MCA. The second direction Y may be perpendicular to the first direction X.

In example embodiments, the bit lines BL may include the pad portions PP having a width greater than that of each of the line portions LP, thereby improving performance of the semiconductor device 1.

In example embodiments, a distance between the pad portions PP may be minimized, thereby increasing a degree of integration of the semiconductor device 1.

Among the bit lines BL, the line portions LP may extend into the first and second extension regions EXTa and EXTb while crossing the memory cell array region MCA. The bit lines BL may be arranged to be spaced apart from each other in the second direction Y. The terms A-type bit lines BLa and B-type bit lines BLb are used in the present disclosure to distinguish bit lines BL with different orientations from each other. Among the bit lines BL arranged to be spaced apart from each other in the second direction Y, the connection portions CP and the pad portions PP of A-type bit lines BLa may be disposed in the first extension region EXTa. Among the bit lines BL arranged to be spaced apart from each other in the second direction Y, the connection portions CP and the pad portions PP of B-type bit lines BLb may be disposed in the second extension region EXTb.

In an example, a distance L2 between end portions of the line portions LP of the A-type bit lines BLa positioned in the memory cell array region MCA and the first extension region EXTa may be greater than a distance LI between end portions of the line portions LP of the B-type bit lines BLb positioned in the memory cell array region MCA and the first extension region EXTa. The end portions of the line portions LP of the A-type bit lines BLa positioned in the first extension region EXTa may be boundary regions between the line portions LP of the A-type bit lines BLa and the connection portions CP.

Accordingly, in the first extension region EXTa, the B-type bit lines BLa may not be disposed between the pad portions PP, adjacent to each other, of the A-type bit lines BLa. In the second extension region EXTb, the B-type bit lines BLb may not be disposed between the pad portions PP, adjacent to each other, of the B-type bit lines BLb.

The bit lines BL may include a first bit line BL1 and a second bit line BL2 adjacent to each other, among the A-type bit lines BLa, and a third bit line BL3 having a portion disposed between the first and second bit lines BL1 and BL2, among the B-type bit lines BLb. In the first extension region EXTa, the pad portions PP of the first and second bit lines BL1 and BL2 may be adjacent to each other, and the third bit line BL3 may not be disposed between the pad portions PP of the first and second bit lines BL1 and BL2.

Referring to FIGS. 1 to 4E, the semiconductor device 1 may further include a substrate SUB, active regions ACT, and isolation regions STIa and STIb.

The substrate SUB may be a semiconductor substrate. The substrate SUB may be provided as a bulk wafer, an epitaxial layer, a silicon on insulator (SOI) layer, or a semiconductor on insulator (SeOI) layer. The substrate SUB may include a group IV semiconductor, a group III-V compound semiconductor, or a group II-VI compound semiconductor. For example, the substrate SUB may be a substrate including at least one of silicon, silicon carbide, germanium, or silicon-germanium. For example, the substrate SUB may be a silicon material, for example, a single crystal silicon substrate including a single crystal silicon material.

The active regions ACT may be disposed on the substrate SUB in the memory cell array region MCA. The active regions ACT may have a shape protruding from the substrate SUB in a vertical direction Z. The active regions ACT may be formed of a semiconductor material the same as that of the substrate SUB, for example, single crystal silicon.

In an example embodiment, the first and second directions X and Y, perpendicular to each other, may be parallel to an upper surface of the substrate SUB, and the vertical direction Z may be perpendicular to the upper surface of the substrate SUB.

Each of the active regions ACT may have a bar shape extending in a direction inclined to the second direction Y, as illustrated in FIGS. 2 and 3, but example embodiments are not limited thereto, and the shape of each of the active regions ACT may be modified into various shapes.

The active regions ACT may include dummy active regions ACTd, adjacent to the first and second extension regions EXTa and EXTb.

The isolation regions STIa and STIb may include a cell isolation region cSTI disposed on a side surface of the cell active region cACT in the memory cell array region MCA, and may include a peripheral isolation region pSTI disposed on the substrate SUB in the first and second extension regions EXTa and EXTb. The isolation regions STIa and STIb may be formed of an insulating material including at least one of silicon oxide and silicon nitride.

The semiconductor device 1 may further include gate trenches GT crossing the cell active regions cACT and the cell isolation region cSTI. Each of the gate trenches GT may have a linear shape extending in the second direction Y.

The semiconductor device 1 may further include gate structures GS and gate capping layers GC on the gate structures GS.

The gate structures GS and the gate capping layers GC may be disposed in the gate trenches GT.

Each of the gate structures GS may include a gate dielectric layer Gox and a gate electrode GE. In each of the gate structures GS, the gate dielectric layer Gox may be disposed on an inner wall of the gate trench GT, and the gate electrode GE may fill a portion of the gate trench GT on the gate dielectric layer Gox. The gate capping layer GC may fill a remaining portion of the gate trench GT on the gate electrode GE. The gate electrode GE and the gate capping layer GC may be sequentially stacked. An upper surface of the gate electrode GE may be disposed on a level lower than that of each of upper surfaces of the active regions ACT.

The gate dielectric layer Gox may be disposed between a bottom surface of the gate electrode GE and a bottom surface of the gate trench GT, between a side surface of the gate electrode GE and a sidewall of the gate trench GT and between a side surface of the gate capping layer GC and the sidewall of the gate trench GT.

Each of the active regions ACT may include first and second source/drain regions SD1 and SD2 disposed in an upper region of the active region ACT, the first and second source/drain regions SD1 and SD2 spaced apart from each other by the gate trench GT. The gate capping layer GC may be disposed between the first and second source/drain regions SD1 and SD2.

In an example embodiment, the gate electrode GE, the gate dielectric layer Gox, and the first and second source/drain regions SDI and SD2 may form a cell transistor TR.

In an example embodiment, the bit lines BL may be disposed on a level different from that of the gate structures GS. For example, the gate structures GS may be disposed on a level lower than that of the bit lines BL.

The gate structures GS may include dummy gate structures GSd adjacent to the first and second extension regions EXTa and EXTb, the dummy gate structures GSd electrically isolated. The dummy gate structures GSd may cross the dummy active regions ACTd.

A distance between the dummy gate structure GSd, adjacent to the first extension region EXTa, and end portions of the line portions LP of the A-type bit lines BLa in the first extension region EXTa may be greater than a distance between the dummy gate structure GSd, adjacent to the first extension region EXTa, and end portions BLbe of the B-type bit lines BLb in the first extension region EXTa.

The semiconductor device 1 may further include a buffer insulating structure 6 on the active regions cACT, the isolation regions STIa and STIb, the gate structures GS, and the gate capping layers GC. The buffer insulating structure 6 may include at least one insulating material. For example, the buffer insulating structure 6 may include a first insulating layer 6a, a second insulating layer 6b, and a third insulating layer 6c being sequentially stacked. The first and third insulating layers 6a and 6c may be formed of silicon oxide, and the second insulating layer 6b may be formed of silicon nitride.

The bit lines BL may be disposed on the buffer insulating structure 6.

The semiconductor device 1 may further include bit line plugs BLP connecting the bit lines BL and the first source/drain regions SDI to each other.

Each of the bit lines BL may include at least one conductive material layer. For example, each of the conductive lines BL may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof, but inventive concepts are not limited thereto. Each of the bit lines BL may include a single layer or multiple layers formed of the above-described materials. For example, each of the bit lines BL may include a first conductive material layer 12a, a second conductive material layer 12b on the first conductive material layer 12a, and a third conductive material layer 12c on the second conductive material layer 12b. The first to third conductive material layers 12a, 12b, and 12c may include different materials. The bit line plugs BLP may extend from the bit lines BL, pass through the buffer insulation structure 6, and be electrically connected to the first source/drain regions SD1 of the active regions ACT. The bit line plugs BLP may be formed of a material the same as that of the first conductive material layer 12a, but example embodiments are not limited thereto. For example, the bit line plugs BLP may be formed of a conductive material different from the first conductive material layer 12a.

The semiconductor device 1 may further include bit line capping patterns BLC on the bit lines BL.

The bit lines BL, the bit line plugs BLP, and the bit line capping patterns BLC may form bit line structures BLS.

Each of the bit line capping patterns BLC may include an insulating material such as silicon nitride or the like. Each of the bit line capping patterns BLC may include at least one insulating material layer. For example, each of the bit line capping patterns BLC may include a first insulating material layer 15, a second insulating material layer 21 on the first insulating material layer 15, and a third insulating material layer 27 on the second insulating material layer 21. In each of the bit line capping patterns BLC, a thickness of the second insulating material layer 21 may be less than a thickness of each of the first and third insulating material layers 15 and 27.

As described above, each of the bit lines BL may include a line portion LP extending into the first and second extension regions EXTa and EXTb while crossing the memory cell array region MCA, the connection portion CP extending from the line portion LP in a direction away from the memory cell array region MCA, and the pad portion PP extending from the connection portion CP in a direction away from the memory cell array region MCA. For example, the first bit line BL1 may include a first line portion LP1 extending into the first extension region EXTa while crossing the memory cell array region MCA, a first connection portion CP1 extending from the first line portion LP1 in a direction away from the memory cell array region MCA, and a first pad portion PP1 extending from the first connection portion CP1 in a direction away from the memory cell array region MCA. The second bit line BL2 may include a second line portion LP2 extending into the first extension region EXTa while crossing the memory cell array region MCA, a second connection portion CP2 extending from the second line portion LP2 in a direction away from the memory cell array region MCA, and a second pad portion PP2 extending from the second connection portion CP2 in a direction away from the memory cell array region MCA. The third bit line BL3 may include a line portion extending into the first extension region EXTa while crossing the memory cell array region MCA, the line portion having an end portion BLbe in the first extension region EXTa.

In the bit lines BL, a minimum distance D2 between the pad portions PP, adjacent to each other, may be less than a minimum distance DI between the line portions LP, adjacent to each other.

The semiconductor device 1 may further include an insulating spacer 18 disposed on side surfaces of end portions of the pad portions PP of the bit lines BL in the first and second extension regions EXTa and EXTb. The insulating spacer 18 may include at least one of a low-K dielectric, silicon oxide, and silicon nitride. The insulating spacer 18 may include at least one insulating layer. The insulating spacer 18 may be formed of a single layer or multiple layers.

The insulating spacer 18 may cover side surfaces of the first insulating material layers 15 aligned with the pad portions PP.

In each of the first and second extension regions EXTa and EXTb, the insulating spacer 18 may be in contact with side surfaces of end portions of the pad portions PP of the bit lines BL and side surfaces of the first insulating material layers 15 on the pad portions PP. In each of the first and second extension regions EXTa and EXTb, the insulating spacers 18 may be connected to each other in the second direction Y.

The semiconductor device 1 may further include an insulating liner 21e extending from the second insulating material layers 21, the insulating liner 21e covering the insulating spacer 18, the insulating liner 21e disposed on the peripheral isolation region STIb.

The semiconductor device 1 may further include a lower interlayer insulating layer 24 disposed on the insulating liner 21e, the lower interlayer insulating layer 24 coplanar with upper surfaces of the second insulating material layers 21. The lower interlayer insulating layer 24 may include an insulating material such as silicon oxide or a low-K dielectric.

The semiconductor device 1 may further include an upper interlayer insulating layer 27e extending from the third insulating material layers 27, the upper interlayer insulating layer 27e disposed on the lower interlayer insulating layer 24. A material of the upper interlayer insulating layer 27e may be different from a material of the lower interlayer insulating layer 24. For example, the lower interlayer insulating layer 24 may include silicon oxide or a low-K dielectric, and the upper interlayer insulating layer 27e may include silicon nitride.

The semiconductor device 1 may further include insulating patterns 33p disposed in the first and second extension regions EXTa and EXTb, the insulating patterns 33p having at least a portion disposed between the pad portions PP of the bit lines BL. The insulating patterns 33p may be spaced apart from each other in the second direction Y. The insulating patterns 33p may include an insulating material such as silicon oxide or silicon nitride.

Hereinafter, the first to third bit lines BL1, BL2, and BL3 and one insulating pattern 33p having a portion disposed between the first and second pad portions PP1 and PP2 will be described.

The insulating pattern 33p may include a first insulating portion 33p1 disposed between the first pad portion PP1 and the second pad portion PP2.

The insulating pattern 33p may further have a second insulating portion 33p2 extending from the first insulating portion 33p1, the second insulating portion 33p2 disposed on a side surface of the first connection portion CP1, and a third insulating portion 33p3 extending from the first insulating portion 33p1, the third insulating portion 33p3 spaced apart from the second insulating portion 33p2, the third insulating portion 33p3 disposed on a side surface of the second connection portion CP2.

The second insulating portion 33p2 may further have a portion covering a side surface of the first line portion LP1, adjacent to the first connection portion CP1. The third insulating portion 33p2 may further have a portion covering a side surface of the second line portion LP2, adjacent to the second connection portion CP2.

The insulating pattern 33p may further have an extension insulating portion 33p4 extending from the first insulating portion 33p1 in a direction away from the memory cell array region MCA.

The extension insulating portion 33p4 may extend into the insulating spacer 18. In the insulating spacer 18, a width in the first direction X of a region, adjacent to the first and second pad portions PP1 and PP2 in the first direction X, may be greater than a width in the first direction X of a region, adjacent to the extension insulating portion 33p4 of the insulating pattern 33p in the first direction X.

The insulating pattern 33p may include the first insulating portion 33p1, the second insulating portion 33p2, the third insulating portion 33p3, and the extension insulating portion 33p4. The insulating pattern 33p may include at least one of a low-K dielectric, silicon oxide, and silicon nitride. The low-K dielectric may be a dielectric having a dielectric constant lower than that of silicon oxide.

The semiconductor device 1 may further include a spacer structure SP. The spacer structure SP may be formed of an insulating material.

The spacer structure SP may include plug spacers 36, inner spacers 30, outer spacers 45, and intermediate spacers 42.

The plug spacers 36 may be disposed on side surfaces of the bit line plugs BLP. Each of the plug spacers 36 may include a spacer pattern 36b and a spacer liner 36a, covering a side surface and a lower surface of the spacer pattern 36b, in the cross-sectional structure illustrated in FIG. 4D.

The inner spacers 30 may be disposed on side surfaces of the bit line structures BLS. The inner spacers 30 may cover side surfaces and lower surfaces of the plug spacers 36, and may cover side surfaces of the bit lines BL and side surfaces of the bit line capping patterns BLC. The intermediate and outer spacers 42 and 45 may be disposed on side surfaces of the bit lines BL and side surfaces of the bit line capping patterns BLC.

In the plane illustrated in FIG. 3A, a first inner spacer 30a, among the inner spacers 30, may include a first inner portion 30a1 covering a side surface of the first line portion LP1 facing the third bit line BL3, a second inner portion 30a2 covering a side surface of the second line portion LP2 facing the third bit line BL3, a third inner portion 30a3 extending from the first inner portion 30a1, the third inner portion 30a3 disposed between the insulating pattern 33p and the first bit line BL1, a fourth inner portion 30a4 extending from the second inner portion 30a2, the fourth inner portion 30a4 disposed between the insulating pattern 33p and the second bit line BL2, and a fifth inner portion 30a5 disposed between the insulating pattern 33p and the insulating spacer 18.

The first inner spacer 30a may further have a lower portion 30L covering a lower surface of the insulating pattern (33p in FIG. 4A).

In the plane illustrated in FIG. 3A, an inner spacer covering both side surfaces and an end portion of the third bit line BL3, among the inner spacers 30, may be referred to as a second inner spacer 30b.

In the plane illustrated in FIG. 3A, a first outer spacer 45a, among the outer spacers 45, may include a first outer portion 45a1 covering a side surface of the first line portion LP1 facing the third bit line BL3, a second outer portion 45a2 covering a side surface of the second line portion LP2 facing the third bit line BL3, and a third outer portion 45a3 extending from the first and second outer portions 45a1 and 45a2, the third outer portion 45a3 covering a side surface in a direction toward the memory cell array region MCA, among side surfaces of the insulating pattern 33p.

In the plane as illustrated in FIG. 3A, a second outer spacer 45b, among the outer spacers 45, may cover both side surfaces and an end portion of the third bit line BL3.

In the plane illustrated in FIG. 3A, a first intermediate spacer 42a, among the intermediate spacers 42, may include a first intermediate spacer 42a1 covering a side surface of the first line portion LP1 facing the third bit line BL3, a second intermediate portion 42a2 covering a side surface of the second line portion LP2 facing the third bit line BL3, and a third intermediate portion 42a3 extending from the first and second intermediate portions 42a1 and 42a2, the third intermediate portion 42a3 covering a side surface in a direction toward the memory cell array region MCA, among sides surfaces of the insulating pattern 33p.

In the plane illustrated in FIG. 3A, a second intermediate spacer 42b, among the intermediate spacers 42, may cover both side surfaces and an end portion of the third bit line BL3.

The inner spacers 30, the intermediate spacers 42, and the outer spacers 45 may be sequentially disposed in a direction away from the bit lines BL.

In an example embodiment, the inner spacers 30 may be in contact with the bit lines BL. The intermediate spacers 42 may be disposed between the inner spacers 30 and the outer spacers 45.

In the plane illustrated in FIG. 3A, the insulating pattern 33p may be disposed between the first inner spacer 30a and the first intermediate spacer 42a. In some example embodiments, when the intermediate spacers 42 are omitted, the insulating pattern 33p may be disposed between the first inner spacer 30a and the first outer spacer 45a.

A thickness of each of the outer spacers 45 may be greater than a thickness of each of the inner spacers 30.

A thickness of each of the intermediate spacers 42 may be greater than a thickness of each of the inner spacers 30.

The inner spacers 30 may include at least one of SiN and SiCN.

The intermediate spacers 42 may include at least one of silicon oxide and a low-K dielectric.

The outer spacers 45 may include at least one of SiN and SiCN.

The semiconductor device 1 may further include contact plugs CNT disposed between the bit line structures BLS.

The contact plugs CNT may be formed of a conductive material.

The contact plugs CNT may include cell contact plugs CNTc disposed in the memory cell array region MCA, the cell contact plugs CNTc electrically connected to the second source/drain regions SD2, and dummy contact plugs CNTd disposed in the first and second extension regions EXTa and EXTb, the dummy contact plugs CNTd disposed on the peripheral isolation region STIb. The dummy contact plugs CNTd may be in contact with the peripheral isolation region pSTI, and may be electrically isolated.

In the first and second extension regions EXTa and EXTb, the dummy contact plugs CNTd may serve to limit and/or prevent deformation of the bit line structures BLS.

Each of the contact plugs CNT may include a lower conductive layer 55, an upper conductive layer 64 on the lower conductive layer 55, and an intermediate conductive layer 61 between the lower conductive layer 55 and the upper conductive layer 64.

The lower conductive layer 55 may include doped polysilicon, for example, polysilicon having an N-type conductivity type. The intermediate conductive layer 61 may include a metal-semiconductor compound layer. The upper conductive layer 64 may include a conductive layer 64b and a barrier layer 64a covering a side surface and a bottom surface of the conductive layer 64b. The barrier layer 64a may include at least one of TiN, TaN, WN, TiSiN, TaSiN, or RuTiN, and the conductive layer 64b may include a metal material such as W.

The lower conductive layers 55 of the cell contact plugs CNTc may be in contact with the second source/drain regions SD2, and the lower conductive layers 55 of the dummy contact plugs CNTd may be in contact with the peripheral isolation region STIb.

The semiconductor device 1 may further include an upper spacer 58 surrounding a side surface of the upper conductive layer 73. The upper spacer 58 may include an insulating material such as silicon oxide or silicon nitride.

The semiconductor device 1 may further include insulating fences IF parallel to each other. Each of the insulating fences IF may have a linear shape extending in the second direction Y. The insulating fences IF may vertically overlap the gate structures GS in the memory cell array region MCA, and may be in contact with the peripheral isolation region STIb in the first and second extension regions EXTa and EXTb.

Each of the insulating fences IF may include first fence portions IFa and second fence portions IFb. The insulating fences IF may be formed of an insulating material such as silicon nitride or silicon oxide.

In the memory cell array region MCA, the first fence portions IFa may separate the cell contact plugs CNTc from each other in the first direction X. In the memory cell array region MCA, the first fence portions IFa may separate the dummy contact plugs CNTd from each other in the first direction X. The second fence portions IFb may be disposed on a level higher than that of the bit lines BL, may pass through a portion of the bit line capping patterns BLC, and may extend from in upper regions of the first fence portions IFa.

The contact plugs CNT may be spaced apart from each other in the second direction Y by the bit line structures BLS, and may be spaced apart from each other in the first direction X by the first fence portions IFa of the insulating fences IF.

The dummy contact plugs CNTd may include first dummy contact plugs CNTd1 and second dummy contact plugs CNTd2. In the first extension region EXTa, the first dummy contact plugs CNTd1 may be disposed between end portions BLbe of the B-type bit lines BLb and the insulating patterns 33p. At least a portion of the first dummy contact plug CNTd1 may be disposed between an end portion BLbe of the B-type bit line BLb and the insulating pattern 33p. In the second extension region EXTb, the first dummy contact plugs CNTd1 may be disposed between end portions of the A-type bit lines BLa and the insulating patterns 33p disposed in the second extension region EXTb. At least a portion of the first dummy contact plug CNTd1 may be disposed between an end portion of the A-type bit line BLa and the insulating pattern 33p disposed in the second extension region EXTb. In the first and second extension regions EXTa and EXTb, the second dummy contact plugs CNTd2 may be disposed between the insulating fences IF and between the bit lines BL. For example, in the first extension region EXTa, the second dummy contact plugs CNTd2 may be disposed between the insulating fences IF, between the first line portion LP1 and the third bit line BL3, and between the second line portion LP2 and the third bit line BL3. Among the dummy contact plugs CNTd, a first dummy contact plug CNTd1, furthest away from the memory cell array region MCA, may be disposed between an insulating fence IF, furthest away from the memory cell array region MCA, and the insulating pattern 33p.

In the plane illustrated in FIG. 3A, the dummy contact plug CNTd2 may be surrounded by the first outer spacer 42a, the second outer spacer 42b, and the insulating fence IF. At least a portion of the dummy contact plug CNTd2 may be disposed between the insulating pattern 33p and an end portion of the third bit line BL3.

The semiconductor device 1 may further include bit line contact structures 72. The bit line contact structures 72 may pass through the bit line capping patterns BLC in the first and second extension regions EXTa and EXTb, and may be electrically connected to the pad portions PP of the bit lines BL. For example, among the bit line contact structures 72, the bit line contact structures 72, disposed in the first extension region EXTa, may pass through the bit line capping pattern BLC, and may be electrically connected to the first and second pad portions PP1 and PP2 of the first and second extension regions BL1 and BL2.

Each of the bit line contact structures 72 may include a first conductive layer 72b and a second conductive layer 72a covering a side surface and a bottom surface of the first conductive layer 72b. The second conductive layer 72a may include at least one of TiN, TaN, WN, TiSiN, TaSiN, or RuTiN, and the first conductive layer 72b may include a metal material such as W.

According to example embodiments, patterns including a conductive material, for example, the dummy contact plugs CNTd, may not be disposed between the pad portions PP, thereby limiting and/or preventing bridge defects in the bit line contact structures 72 disposed on the pad portions PP. Accordingly, the semiconductor device 1 may have improved reliability.

The semiconductor device 1 may further include conductive patterns 75i and 75p. Each of the conductive patterns 75i and 75p may include at least one conductive material. Each of the conductive patterns 75i and 75p may include at least one of Cu, Ti, Ta, Ru, W, Mo, Pt, Ni, Co, TiN, TaN, WN, NbN, TiAl, TiAlN, TiSi, TiSiN, TaSi, TaSiN, RuTiN, and NiSi.

The conductive patterns 75i and 75p may be connected to the bit line contact structures 72 in the first and second extension regions EXTa and EXTb, and may include first conductive patterns 75i extending onto the upper interlayer insulating layer 27e, and second conductive patterns 75p electrically connected to the cell contact plugs CNTc in the memory cell array region MCA.

The first conductive patterns 75i may be interconnection lines for electrically connecting the bit lines BL to a peripheral circuit such as a sense amplifier or the like. The second conductive patterns 75p may be landing pads. The second conductive patterns 75p may be electrically connected to the second source/drain regions SD2 of the cell transistors TR by the cell contact plugs CNTc.

The first conductive patterns 75i may be referred to as “bit line interconnection lines” or “interconnection lines,” and the second conductive patterns 75p may be referred to as “conductive pads.”

The semiconductor device 1 may further include an insulating separate pattern 78, an etch stop layer 85, a data storage structure DS, and a peripheral insulating layer 95.

The insulating separation pattern 78 may be disposed on side surfaces of the conductive patterns 75i and 75p, and may extend downwardly. The insulating separation pattern 78 may be disposed on a level higher than that of the bit lines BL. Upper surfaces of the dummy contact plugs CNTd may be covered by the insulating separation pattern 78.

The etch stop layer 85 may be disposed on the insulating separation pattern 78 and the conductive patterns 75i and 75p, and may be formed of an insulating material. The peripheral insulating layer 95 may be disposed on the etch stop layer 85 in the first and second extension regions EXTa and EXTb.

The data storage structure DS may be disposed in the memory cell array region MCA.

In an example, the data storage structure DS may be a capacitor storing data in DRAM. For example, the data storage structure DS may be a capacitor of DRAM including first electrodes 88 passing through the etch stop layer 85, the first electrodes 88 electrically connected to the second conductive patterns 75p, a dielectric layer 90 covering the first electrodes 88 and the etch stop layer 85, and a second electrode 92 on the dielectric layer 90. The dielectric layer 90 may include a high-k dielectric, silicon oxide, silicon nitride, silicon oxynitride, or combinations thereof. The high-k dielectric may be a dielectric having a dielectric constant higher than that of silicon oxide.

In another example, the data storage structure DS may be a structure storing data on a memory, different from DRAM. For example, in the data storage structure DS, the dielectric layer 90 may include a ferroelectric layer capable of recording data using a polarization state.

Hereinafter, various modifications to the above-described embodiment will be described to increase a degree of integration and improve reliability of the semiconductor device 1. Hereinafter, various modifications of elements of the above-described example embodiment will be described. The various modifications of the elements of the above-described example embodiment described below will mainly be described with respect to elements to be modified or elements to be replaced. In addition, the elements that are modifiable or replaceable to be described below are described with reference to drawings below, but the elements that are modifiable or replaceable are combined with each other, or are combined with the elements described above to configure a semiconductor device according to an example embodiment.

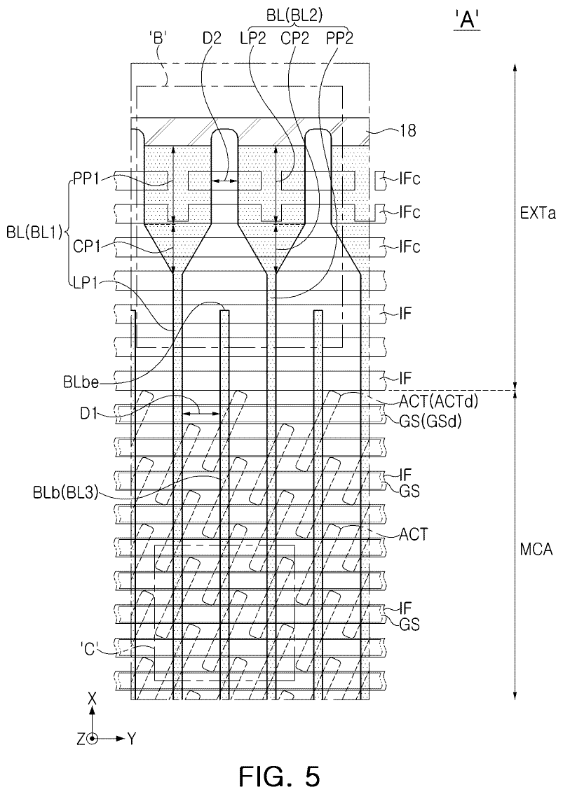

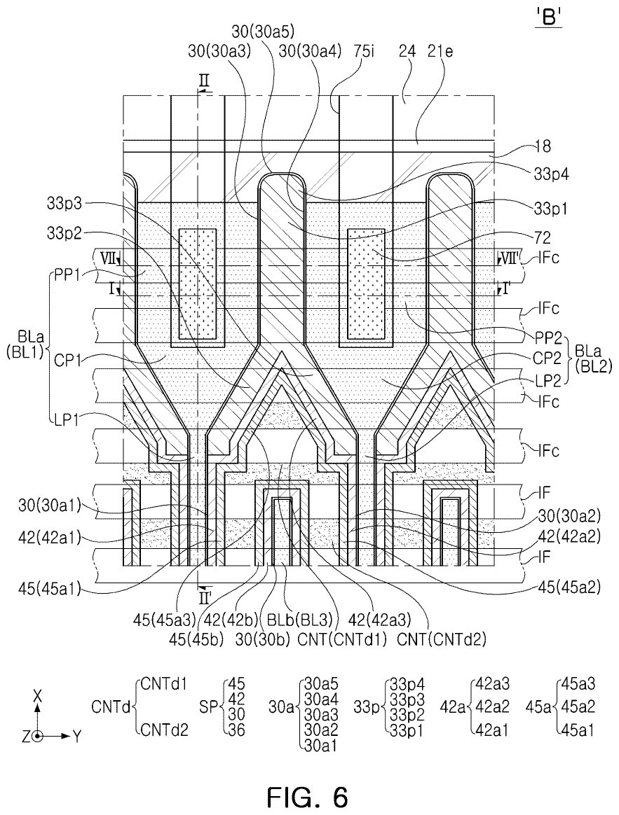

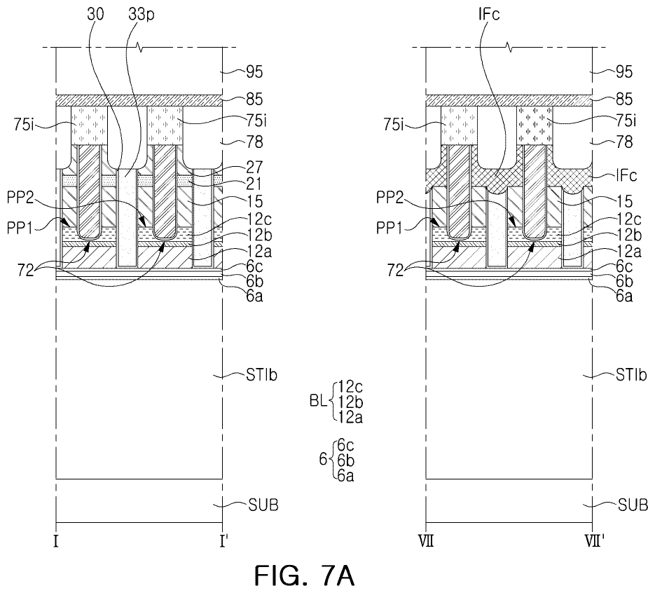

A modification of a semiconductor device according to an example embodiment of inventive concepts will be described with reference to FIGS. 5 to 7B. In FIGS. 5 to 7B, FIG. 5 is a plan view of a modified portion in FIG. 2, FIG. 6 is a partially enlarged view of a region indicated by “A” of FIG. 5, FIG. 7A is a cross-sectional view of regions taken along lines I-I′ and VII-VII′ of FIG. 6, and FIG. 7B is a cross-sectional view of a region taken along line II-II′ of FIG. 6.

In a modification, referring to FIGS. 5 to 7B, the semiconductor device 1 may further include outer insulating fences IFc crossing the connection portions CP, the pad portions PP, and the insulating patterns 33p in the first and second extension regions EXTa and EXTb.

The bit line contact structures 72 may pass through an outer insulating fence disposed on the pad portions PP, among the outer insulating fences IFc, and may be connected to the pad portions PP.

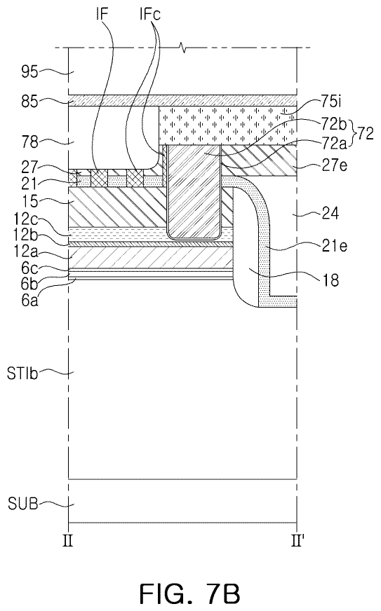

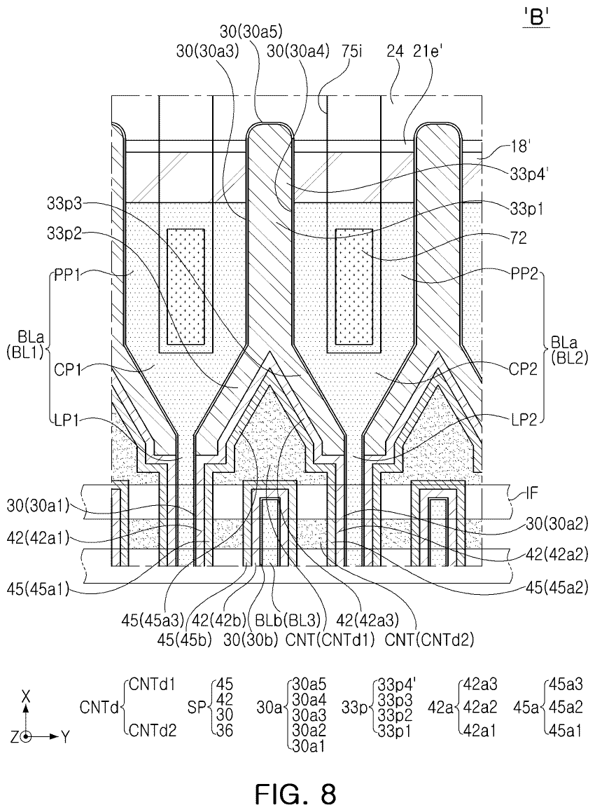

A modification of a semiconductor device according to an example embodiment of inventive concepts will be described with reference to FIG. 8. FIG. 8 is a plan view of a modified portion in FIG. 3A.

In a modification, referring to FIG. 8, the extension insulating portion 33p4 in FIG. 3A may be modified into an extension insulating portion 33p4′ passing through the insulating spacer (18 in FIG. 3A). Accordingly, the insulating spacer (18 in FIG. 3A) may be modified into insulating spacers 18′ spaced apart from each other in the second direction Y by the extension insulating portion 33p4′.

The extension insulating portion 33p4′ may pass through the insulating liner (21e in FIG. 3A) in contact with the insulating spacer (18 in FIG. 3A) in FIG. 3A. The insulating liner (21e in FIG. 3A) may be in contact with the insulating spacers 18′ spaced apart from each other in the second direction Y, and may be modified into insulating liners 21e′ spaced apart from each other in the second direction Y by the extension insulating portion 33p4′.

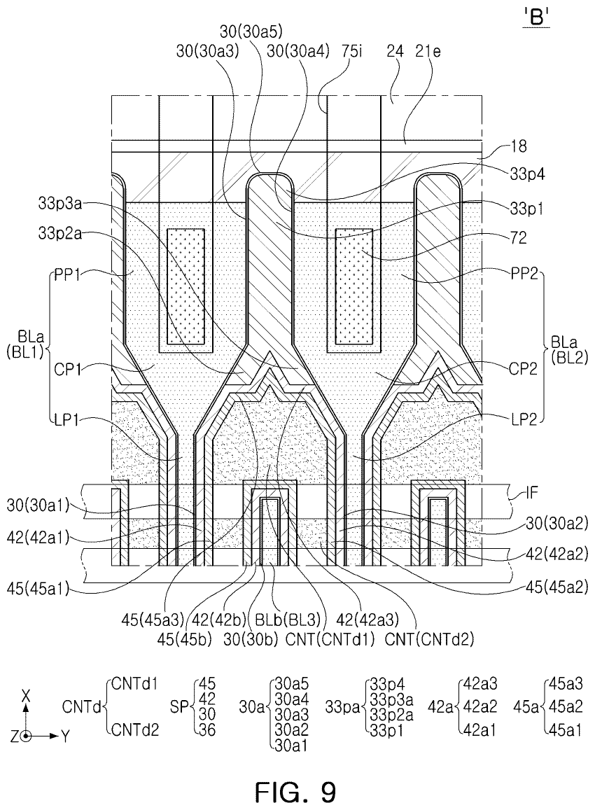

A modification of a semiconductor device according to an example embodiment of inventive concepts will be described with reference to FIG. 9. FIG. 9 is a plan view of a modified portion in FIG. 3A.

In a modification, referring to FIG. 9, the above-described second insulating portion (33p2 in FIG. 3A) covering a side surface of the first line portion LP1, adjacent to the first connection portion CP1, while covering a side surface of the first connection portion CPI may be modified into a second insulating portion 33p2a spaced apart from the first line portion LP1, the second insulating portion 33p2a covering a portion of the side surface of the first connection portion CP1. The above-described third insulating portion (33p3 in FIG. 3A) covering a side surface of the second line portion LP2, adjacent to the second connection portion CP2, while covering a side surface of the second connection portion CP2 may be modified into a third insulating portion 33p3a spaced apart from the second line portion LP2, the third insulating portion 33p3a covering a portion of the side surface of the second connection portion CP2. Accordingly, the above-described insulating pattern (33p in FIG. 3A) may be modified into an insulating pattern 33pa including the second and third insulating portions 33p2a and 33p3a, together with the first insulating portion 33p1 and the extension insulating portion 33p4.

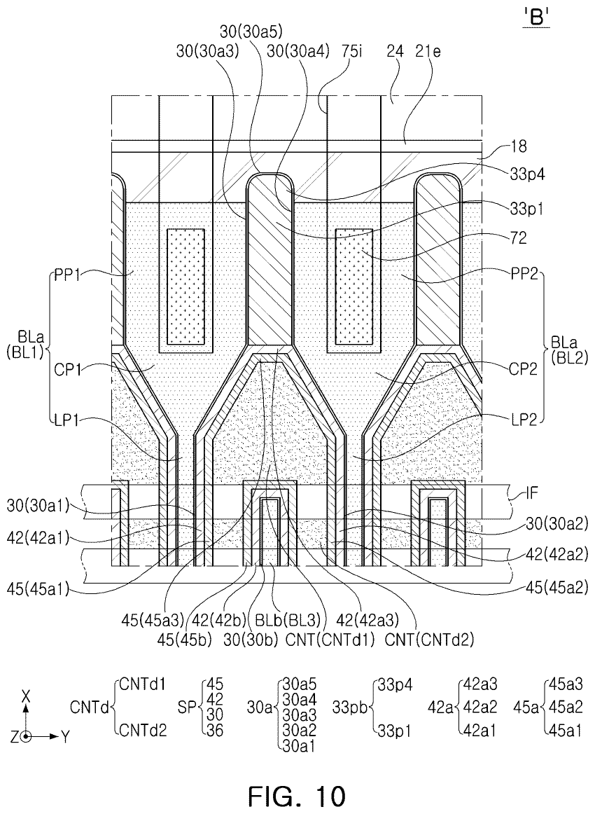

A modification of a semiconductor device according to an example embodiment of inventive concepts will be described with reference to FIG. 10. FIG. 10 is a plan view of a modified portion in FIG. 3A.

In a modification, referring to FIG. 10, the second insulating portion (33p2 in FIG. 3A) and the third insulating portion (33p3 in FIG. 3A) described above may be omitted. Accordingly, the above-described insulating pattern (33p in FIG. 3A) may be modified into an insulating pattern 33pb including the first insulating portion 33p1 and the extension insulating portion 33p4.

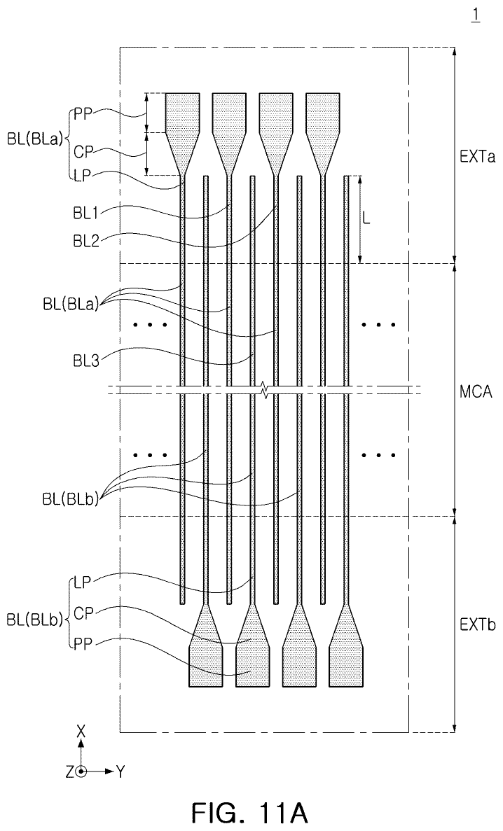

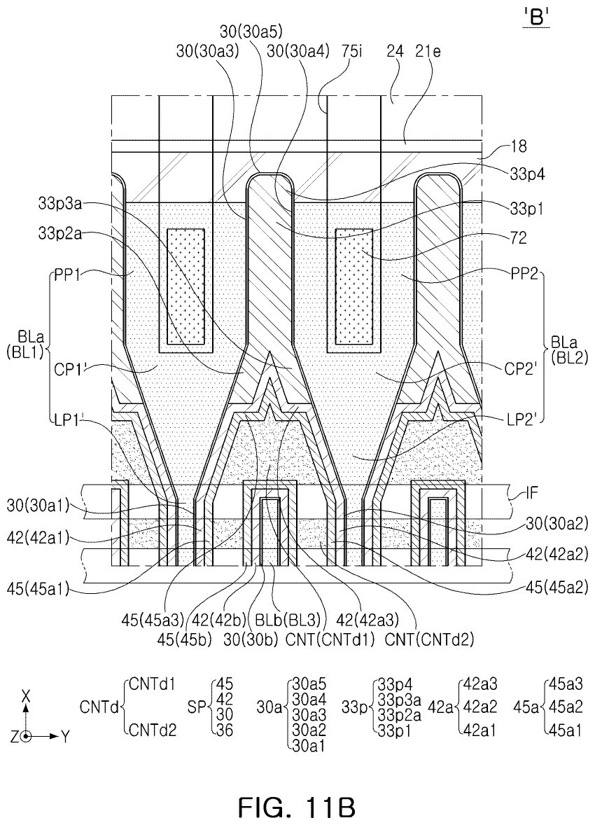

A modification of a semiconductor device according to an example embodiment of inventive concepts will be described with reference to FIGS. 11A and 11B. FIG. 11A is a plan view of a modified portion in FIG. 1, and FIG. 11B is a plan view of a modified portion in FIG. 3A.

In a modification, referring to FIGS. 11A and 11B, the first and second line portions (LP1 and LP2 in FIG. 3A) and the first and second connection portions (CP1 and CP2 in FIG. 3A) described above may be modified into first and second line portions LP1′ and LP2′ and first and second connection portions CP1′ and CP2′ illustrated in FIGS. 11A and 11B. For example, a distance L between the memory cell array region MCA and the first and second connection portions CP1′ and CP2′ may be substantially the same as a distance L between the memory cell array region MCA and an end portion of the third bit line BL3.

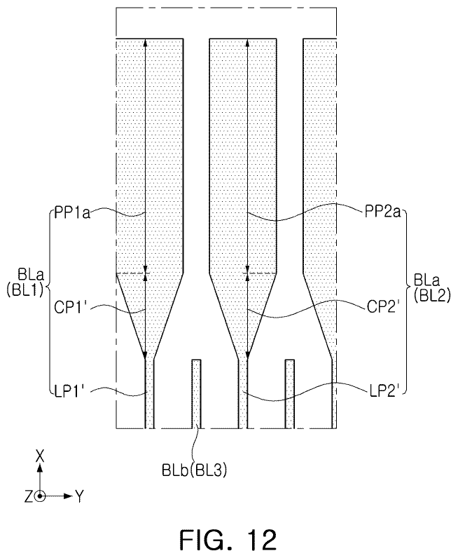

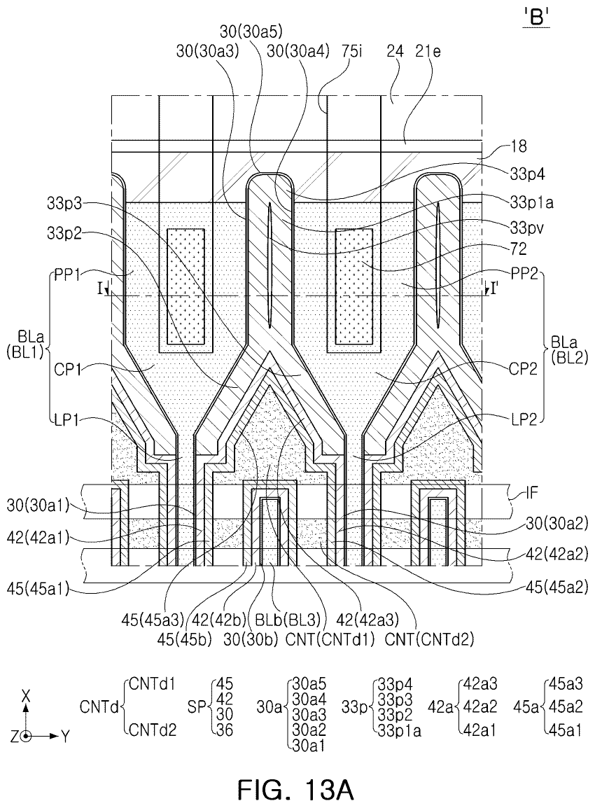

A modification of a semiconductor device according to an example embodiment of inventive concepts will be described with reference to FIG. 12. FIG. 12 is a plan view illustrating a modification of the first and second pad portions in FIG. 3A.

In a modification, referring to FIG. 12, the above-described first and second pad portions (PP1 and PP2 in FIG. 3A) may be modified into first and second pad portions PP1a and PP2a illustrated in FIG. 12.

A length of each of the first and second pad portions PP1a and PP2a in the first direction X may be about two or more times, greater than a width of each of the first and second pad portions PP1a and PP2a in the second direction Y.

The length of each of the first and second pad portions PP1a and PP2a in the first direction X may be about three or more times, greater than the width of each of the first and second pad portions PP1a and PP2a in the second direction Y.

The first and second line portions (LP1 and LP2 in FIG. 3A) and the first and second connection portions (CP1 and CP2 in FIG. 3A) described above may be modified into the first and second line portions LP1′ and LP2′ and the first and second connection portions CP1′ and CP2′ illustrated in FIGS. 11A and 11B.

The length of each of the first and second pad portions PP1a and PP2a in the first direction X may be about two or more times, greater than a length of each of the first and second connection regions CP1′ and CP2′ in the first direction X.

The length of each of the first and second pad portions PP1a and PP2a in the first direction X may be about three or more times, greater than the length of each of the first and second connection regions CP1′ and CP2′ in the first direction X.

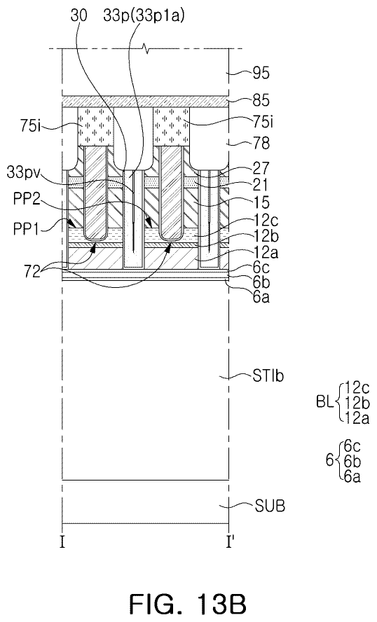

A modification of a semiconductor device according to an example embodiment of inventive concepts will be described with reference to FIGS. 13A and 13B. FIG. 13A is a plan view of a modified portion in FIG. 3A, and FIG. 13B is a cross-sectional view taken along line I-I′ of FIG. 13A.

In a modification, referring to FIGS. 13A and 13B, the first insulating portion 33p1 of the insulating pattern (33p in FIGS. 3A and 4A) described above may be modified into a first insulating portion 33p1a having a seam or a void 33pv formed therein.

The void 33pv may reduce parasitic capacitance between the first and second pad portions PP1 and PP2, thereby reducing RC delay in the bit lines BL.

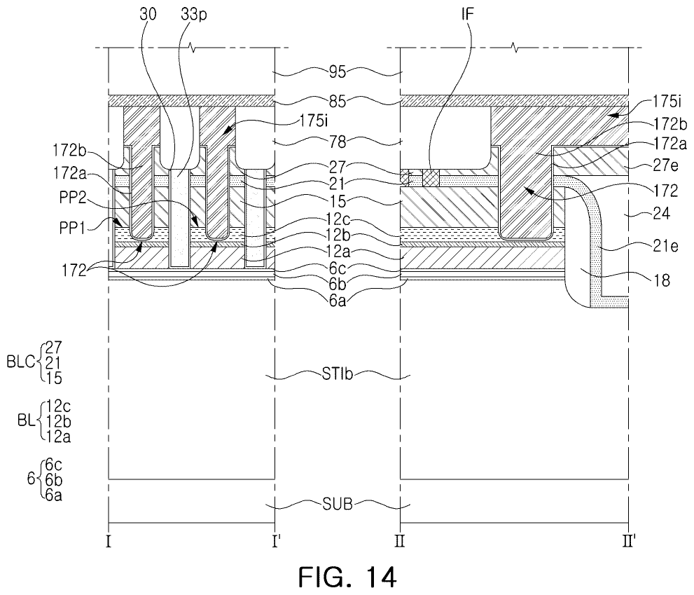

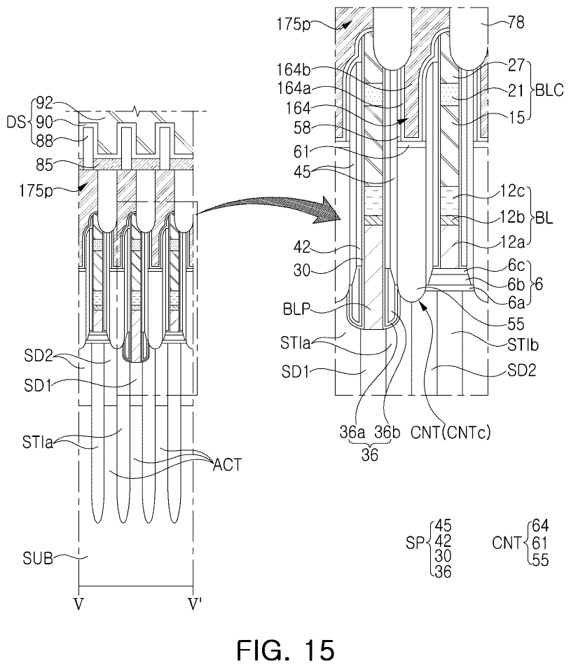

A modification of a semiconductor device according to an example embodiment of inventive concepts will be described with reference to FIGS. 14 and 15. FIG. 14 is a cross-sectional view of a modified portion in FIG. 4A, and FIG. 15 is a cross-sectional view of a modified portion in FIG. 4D.

In a modification, referring to FIGS. 14 and 15, the bit line contact structure (72 in FIG. 4A) and the first conductive pattern (75i in FIG. 4A) described above may be modified into first conductive patterns 172 and 175i formed integrally. The first conductive patterns 172 and 175i may include a plug portion 172 passing through the bit line capping pattern BLC, the plug portion 172 electrically connected to the pad portions PPI and PP2, and an interconnection line portion 175i extending from the plug portion 172, the interconnection line portion 175i disposed at a level higher than that of the bit line capping pattern BLC. The first conductive patterns 172 and 175i may include a conductive layer 172b and a barrier layer 172a below the conductive layer 172b.

The upper conductive layer (64 in FIG. 4D) and the second conductive pattern (75p in FIG. 4D) may be modified into second conductive patterns 164 and 175p formed integrally. The second conductive patterns 164 and 175p may include a plug portion 164 forming an upper region of the cell contact plug CNTc, and a pad portion 175p extending from the plug portion 164, the pad portion 175p disposed on a level higher than that of the bit line structure BLS. The second conductive patterns 164 and 175p may include a conductive layer 164b and a barrier layer 164a below the conductive layer 164b.

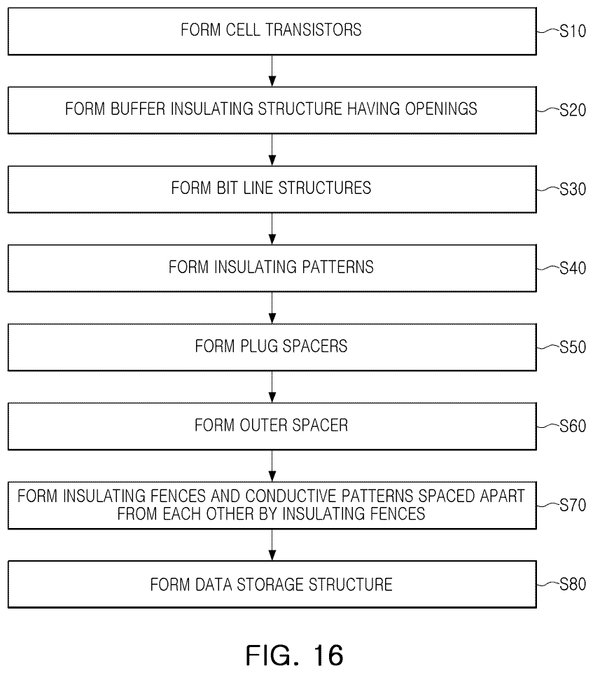

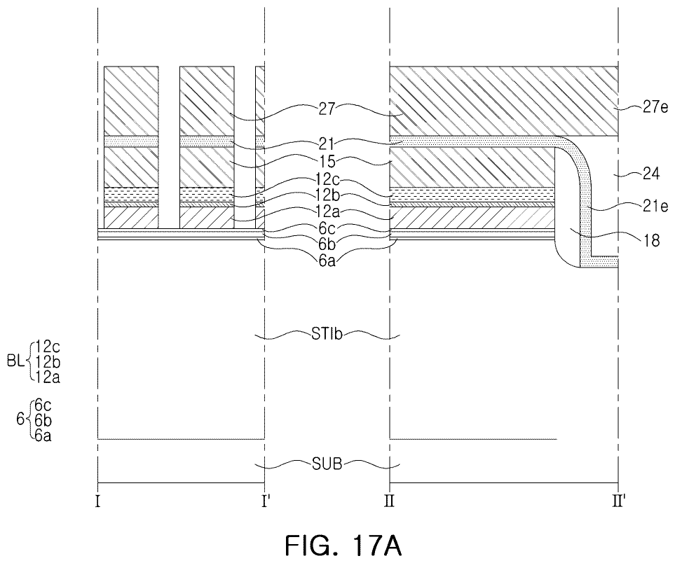

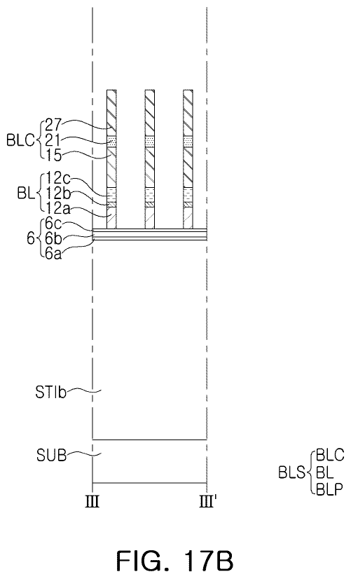

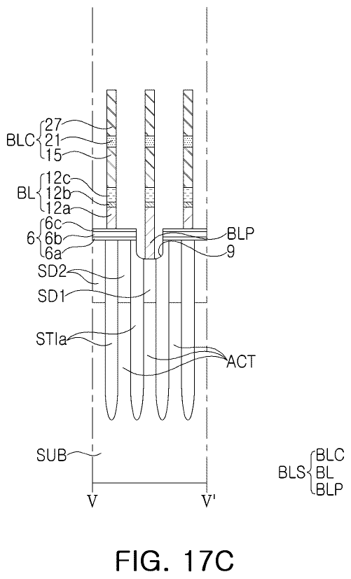

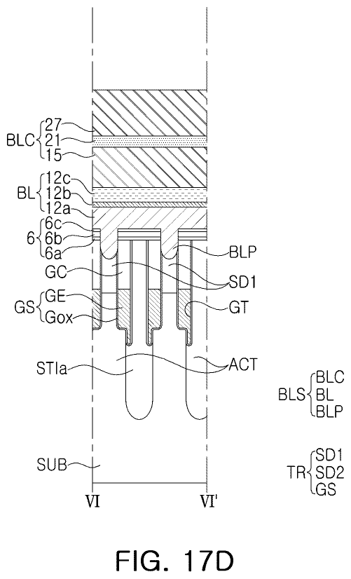

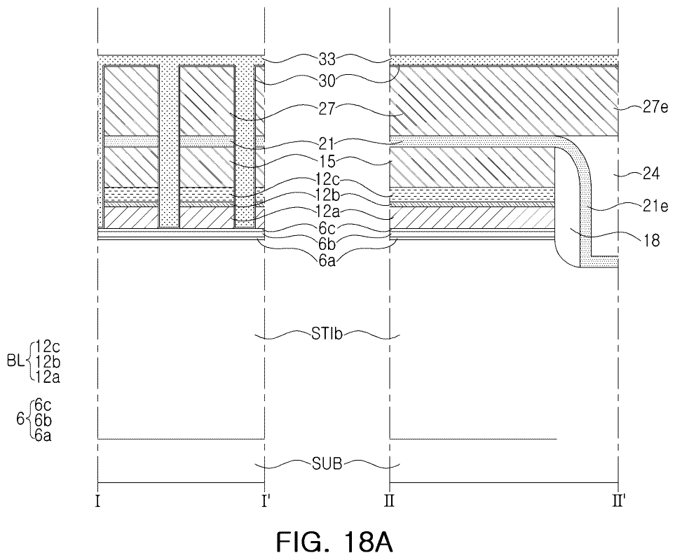

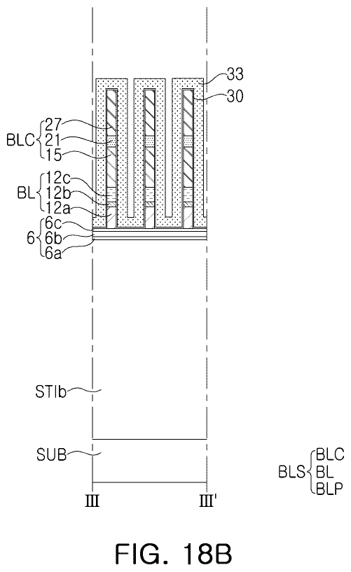

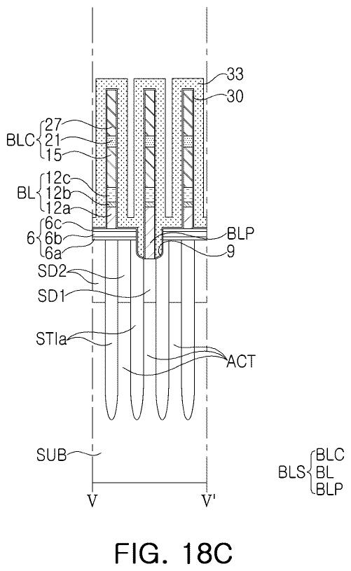

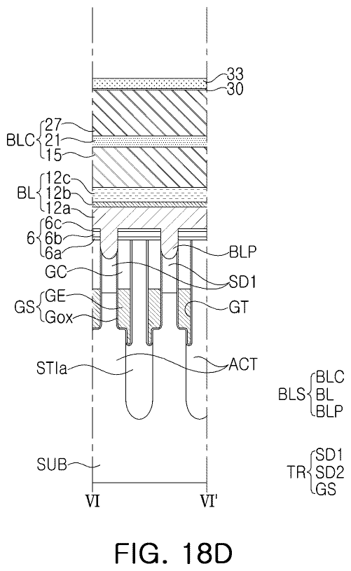

Referring to FIGS. 16, 17A, 17B, 17C, 18A, 18B, and 18C together with FIGS. 1 to 3B, an example of a method of manufacturing a semiconductor device according to an example embodiment of inventive concepts will be described. FIG. 16 is a process flowchart illustrating an example of a method of manufacturing a semiconductor device according to an example embodiment of inventive concepts, and FIGS. 17A to 18C are cross-sectional views of an example of a method of manufacturing a semiconductor device according to an example embodiment of inventive concepts. In FIGS. 17A to 18C, FIGS. 17A and 18A are cross-sectional views of regions taken along lines I-I′ and II-II′ of FIG. 3A, FIGS. 17B and 18B are cross-sectional views of a region taken along lines III-III′ of FIG. 3A, and FIGS. 17C and 18C are cross-sectional views a region taken along line V-V′ of FIG. 3B.

Referring to FIGS. 16, 17A, 17B, and 17C together with FIGS. 1 to 3B, a cell transistor TR may be formed (S10). Forming the cell transistor TR may include forming active regions ACT and isolation regions STIa and STIb on a substrate SUB, forming gate trenches GT crossing a cell isolation region STIa, among the isolation regions STIa and STIa, and the active regions ACT, and forming gate patterns GS and GC in the gate trenches GT.

Forming the cell transistor TR may further include forming first and second source/drain regions SD1 and SD2 in the active regions ACT.

Each of the gate patterns GS and GC may include a gate structure GS and a gate capping layer GC on the gate structure GS. Each of the gate structures GS may include a gate dielectric layer Gox and a gate electrode GE. In each of the gate structures GS, the gate dielectric layer Gox may be formed on an inner wall of the gate trench GT, and the gate electrode GE may fill a portion of the gate trench GT, on the gate dielectric layer Gox. The gate capping layer GC may fill a remaining portion of the gate trench GT, on the gate electrode GE. The gate capping layer GC may be formed of an insulating material.

The cell transistor TR may include the gate electrode GE, the gate dielectric layer Gox, and the first and second source/drain regions SD1 and SD2.

The isolation regions STIa and STIb may include a cell isolation region STIa in the memory cell array region MCA, and a peripheral isolation region STIb in the first and second extension regions EXTa and EXTb. The isolation regions STIa and STIb may be formed of an insulating material. The isolation regions STIa and STIb may be shallow trench isolation.

The memory cell array region MCA may be disposed between the first extension region EXTa and the second extension region EXTb.

A buffer insulating structure 6 having openings 9 may be formed (S20). The buffer isolation structure 6 may cover the cell active regions ACT, the isolation regions STIa and STIb, and the gate patterns GS and GC, and the openings 9 may expose the first source/drain regions SD1.

The buffer insulating structure 6 may include a first insulating layer 6a, a second insulating layer 6b, and a third insulating layer 6c being sequentially stacked. The first and third insulating layers 6a and 6c may be formed of silicon oxide, and the second insulating layer 6b may be formed of silicon nitride.

Bit line structures BLS may be formed (S30).

Forming the bit line structures BLS may include a plate pattern formed on the buffer insulating structure 6, the plate pattern connected to the first source/drain regions SDI exposed by the openings 9, the plate pattern having an end portion formed on the peripheral isolation region STIb, forming an insulating spacer 18 on a side surface of the plate pattern, forming an upper surface of the plate pattern, the insulating spacer 18, and the peripheral isolation region STIb, forming a preliminary interlayer insulating layer, forming an interlayer insulating layer 24 by planarizing a preliminary interlayer insulating layer until an upper surface of the insulating liner on the upper surface of the plate pattern is exposed, forming an upper insulating layer on the insulating liner, on the upper surface of the plate pattern, and the interlayer insulating layer 24, and performing a patterning process.

Performing the patterning process may include patterning the plate pattern, the insulating liner, and the upper insulating layer being sequentially stacked.

The plate pattern may include at least one conductive layer sequentially stacked and a lower insulating layer on the at least one conductive layer. The at least one conductive layer may be patterned to form bit lines BL and bit line plugs BLP connecting the bit lines BL and the first source/drain regions SDI to each other.

The lower insulating layer, the insulating liner, and the upper insulating layer may be patterned to form bit line capping patterns BLC. For example, each of the bit line capping patterns BLC may include a first insulating material layer 15, a second insulating material layer 21, and a third insulating material layer 27 being sequentially stacked. The first insulating material layer 15 may be formed by patterning the lower insulating layer, the second insulating material layer 21 may be formed by patterning the insulating liner, and the third insulating material layer 27 may be formed by patterning the upper insulating layer.

A portion of the insulating liner may be formed as an insulating liner 21e remaining between the insulating spacer 18 and the interlayer insulating layer 24 and between the peripheral isolation region STIb and the interlayer insulating layer 24, and a portion of the upper insulating layer may be formed as an upper interlayer insulating layer 27e remaining on the interlayer insulating layer 24.

The bit lines BL, the bit line plugs BLP, and the bit line capping patterns BLC may form bit line structures BLS.

The bit lines BL may have a planar shape, as illustrated in FIGS. 1 to 3B. The planar shape of the bit lines BL may be understood from the description of the semiconductor device 1 with reference to FIGS. 1 to 4E.

Referring to FIGS. 16, 18A, 18B, and 18C together with FIGS. 1 to 3B, an insulating layer 33, covering side surfaces and upper surfaces of the bit line structures BLS, bottom surfaces of spaces between the bit line structures BLS, and an upper surface of the upper interlayer insulating layer 27e, may be formed.

In an example embodiment, the insulating layer 33 may be formed to fill a space between the pad portions PP spaced apart from each other by the second distance D2, as illustrated in FIGS. 1 to 3A, and not to fill a space between the line portions LP spaced apart from each other by the first distance D1. For example, the insulating layer 33 having a first thickness may conformally cover side surfaces of the line portions LP, and the first thickness may be equal to half of the second distance D2, or may be greater than half of the second distance D2.

In an example embodiment, an inner spacer 30 may be formed before the insulating layer 33 is formed. Accordingly, the insulating layer 33 may be formed on the inner spacer 30.

Referring to FIG. 16 together with FIGS. 1 to 4E, insulating patterns 33p may be formed (S40). For example, the insulating layer (33 in FIGS. 18A to 18C) may be patterned to form the insulating patterns 33p remaining between the connection portions CP and between the pad portions PP. In some example embodiments, the insulating layer (33 in FIGS. 18A to 18C) may be patterned to form insulating patterns (33pb in FIG. 10) remaining between the pad portions PP.

A plug spacer 36 may be formed (S50). The plug spacer 36 may be formed on a side surface of the bit line plug BLP in the opening 9. The plug spacer 36 may include a spacer pattern 36b and a spacer liner 36a covering a side surface and a lower surface of the spacer pattern 36b.

The outer spacer 45 may be formed (S60). The outer spacer 45 may be formed on side surfaces of the bit lines BL, the bit line capping patterns BLC, and the insulating patterns 33p. In some example embodiments, an intermediate spacer 42 may be formed before the outer spacer 45 is formed.

Insulating fences IF and conductive patterns CNT spaced apart from the insulating fences IF may be formed (S70). The conductive patterns CNT may be contact plugs described above.

The insulating fences IF may be formed to partially pass through the bit line capping patterns BLC and extend between the bit lines BL.

Forming the conductive patterns, that is, the contact plugs CNT may include forming a first material layer filling a space between the line portions LP and a space between the connection portions CP, separating the first material layers from each other in the first direction X by forming the insulating fences IF, forming a lower conductive layer 55 to by partially etching the separated first material layers, forming an upper spacer 58 on a side surface of an upper space of the lower conductive layer 55, forming an intermediate conductive layer 61 on the lower conductive layer 55 by performing a silicide process, and forming an upper conductive layer 64 on the intermediate conductive layer 61.

While the upper conductive layer 64 is formed, bit line contact structures 72 passing through the bit line capping patterns BLC in the first and second extension regions EXTa and EXTb, the bit line contact structures 72 electrically connected to the pad portions PP of the bit lines BL may be formed. The upper conductive layer 64 and the bit line contact structures 72 may be simultaneously formed.

Subsequently, a conductive layer may be formed. The conductive layer may be patterned to form conductive patterns 75i and 75p. An insulating separation pattern 78 passing between the conductive patterns 75i and 75p may be formed. An etch stop layer 85 may be formed on the conductive patterns 75i and 75p and the insulating separation pattern 78.

The conductive patterns 75i and 75p may include first conductive patterns 75i connected to the bit line contact structures 72 in the first and second extension regions EXTa and EXTb, the first conductive patterns 75i extending onto the upper interlayer insulating layer 27e, and second conductive patterns 75p electrically connected to the cell contact plugs CNTc in the memory cell array region MCA.

A data storage structure DS may be formed (S80). The data storage structure DS may be formed in the memory cell array region MCA. The data storage structure DS may include first electrodes 88 passing through the etch stop layer 85, the first electrodes 88 electrically connected to the second conductive patterns 75p, a dielectric layer 90 covering the first electrodes 88 and the etch stop layer 85, and a second electrode 92 on the dielectric layer 90.

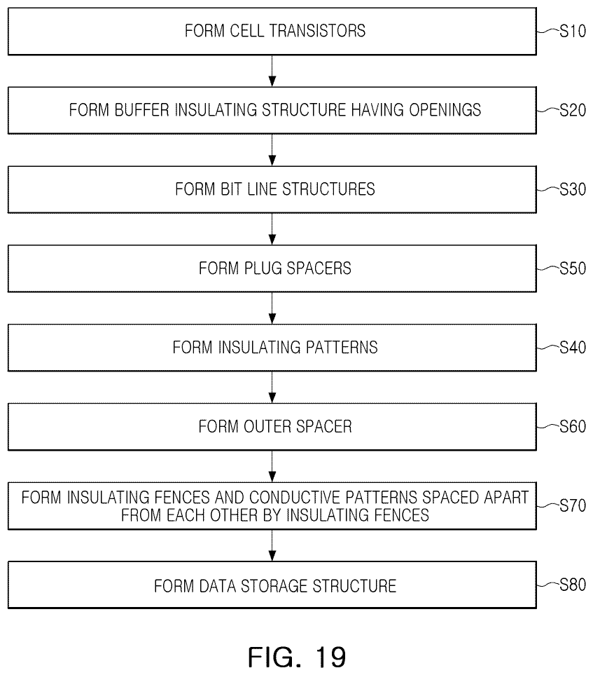

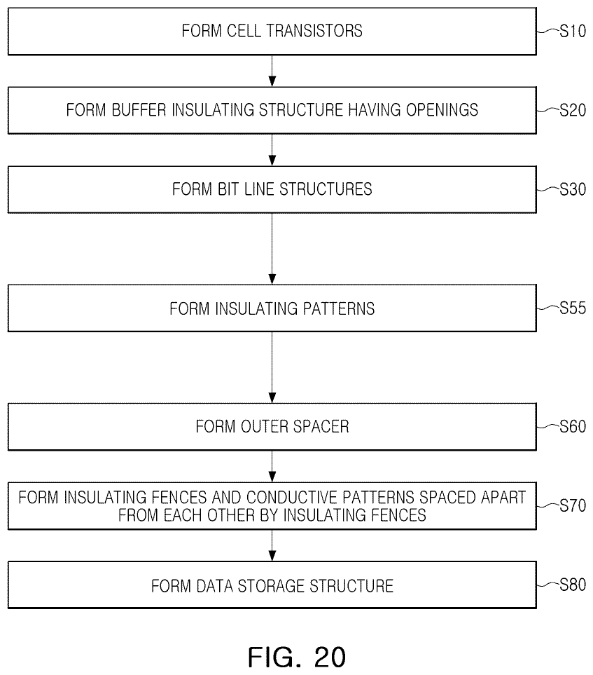

A modification of the above-described method of manufacturing a semiconductor device according to an example embodiment of inventive concepts will be described with reference to each of FIGS. 19 and 20. FIG. 19 is a process flowchart illustrating a modification of the method of manufacturing a semiconductor device according to an example embodiment of inventive concepts, and FIG. 20 is a process flowchart illustrating another modification of the method of manufacturing a semiconductor device according to an example embodiment of inventive concepts.

In a modification, referring to FIG. 19, FIG. 16 illustrates that an operation (S50) of forming the plug spacer (36 in FIG. 4D) is performed after an operation (S40) of forming the insulating patterns (33p in FIGS. 3A and 4A) is performed, but example embodiments are not limited thereto. For example, as illustrated in FIG. 19, the operation (S40) of forming the insulating patterns (33p in FIGS. 3A and 4A) may be performed after the operation (S50) of forming the plug spacer (36 in FIG. 4D) is performed. For example, before the insulating layer 33 described with reference to FIGS. 18A to 18C is formed, the plug spacer (36 in FIG. 4D) may be formed in the opening 9. Subsequently, the insulating layer 33 illustrated in FIGS. 18A to 18C may be formed, and the insulating layer 33 may be patterned to form the insulating patterns (33p in FIGS. 3A and 4A).

In another modification, referring to FIG. 20, FIG. 16 illustrates that the operation (S50) of forming the plug spacer (36 in FIG. 4D) is performed after the operation (S40) of forming the insulating patterns (33p in FIGS. 3A and 4A) is performed, but example embodiments are not limited thereto. For example, as illustrated in FIG. 20, the operation (S40) of forming the insulating patterns (33p in FIGS. 3A and 4A) and the operation (S50) of forming the plug spacer (36 in FIG. 4D) described above may be simultaneously performed. Accordingly, the operation (S40) of forming the insulating patterns (33p in FIGS. 3A and 4A) and the operation (S50) of forming the plug spacer (36 in FIG. 4D) described above may be replaced with an operation (S55) of forming the insulating patterns (33pb in FIG. 10) and the plug spacer (36 in FIG. 4D), performed simultaneously therewith. For example, an isotropic etching process may be performed on the insulating layer 33 illustrated in FIGS. 18A to 18C to simultaneously form the plug spacer (36 in FIG. 4D) remaining in the opening 9 and the insulating patterns (33pb in FIG. 10) remaining between the pad portions PP. In this case, the plug spacer (36 in FIG. 4D) and the insulating patterns (33pb in FIG. 10) may be formed of the same material.

According to example embodiments, bit lines may include pad portions having an increased width, thereby improving performance of a semiconductor device.

According to example embodiments, a semiconductor device may minimize a distance between pad portions of bit lines, thereby increasing a degree of integration of the semiconductor device.

According to example embodiments, a method of filling pad portions of bit lines with an insulating material may be provided, thereby limiting and/or preventing bridge defects in bit line contact structures disposed on the pad portions of the bit lines. Accordingly, a semiconductor device may have improved reliability.

While example embodiments have been shown and described above, it will be apparent to those skilled in the art that modifications and variations could be made without departing from the scope of inventive concepts as defined by the appended claims.

What is claimed is:

1. A semiconductor device comprising:
a structure including a first extension region and a memory cell array region, the first extension region being adjacent to the memory cell array region;
a first bit line including a first line portion extending into the first extension region while crossing the memory cell array region in a first direction, a first connection portion extending from the first line portion in the first extension region, and a first pad portion extending from the first connection portion in the first extension region;
a second bit line including a second line portion extending into the first extension region while crossing the memory cell array region in the first direction, a second connection portion extending from the first line portion in the first extension region, and a second pad portion extending from the second connection portion in the first extension region; and
a third bit line between the first line portion and the second line portion in the memory cell array region and the first extension region, the third bit line including a first end portion in the first extension region, wherein
a width of the first pad portion in a second direction and a width of the second pad portion in the second direction each are greater than a width of the first line portion in the second direction and a width of second line portion in the second direction,
the second direction is perpendicular to the first direction, and
a minimum distance between the first pad portion and the second pad portion is less than a minimum distance between the first line portion and the third bit line.

2. The semiconductor device of claim 1, further comprising:
an insulating pattern,
wherein the insulating pattern includes a first insulating portion between the first pad portion and the second pad portion.

3. The semiconductor device of claim 2, wherein
the insulating pattern further includes an extension insulating portion, and
the extension insulating portion extends from the first insulating portion in a direction away from the memory cell array region.

4. The semiconductor device of claim 2, wherein
the insulating pattern further includes a second insulating portion extending from the first insulating portion and a third insulating portion extending from the first insulating portion,
the second insulating portion is on a side surface of the first connection portion,
the third insulating portion is spaced apart from the second insulating portion, and
the third insulating portion is on a side surface of the second connection portion.

5. The semiconductor device of claim 2, further comprising:
contact plugs spaced apart from each other, wherein
the contact plugs include cell contact plugs disposed in the memory cell array region and dummy contact plugs in the first extension region,
the dummy contact plugs are electrically isolated, and
the dummy contact plugs include a first dummy contact plug between the insulating pattern and the first end portion of the third bit line.

6. The semiconductor device of claim 2, further comprising:
a first outer spacer, wherein
the first outer spacer includes a first outer portion on a side surface of the first line portion facing the third bit line, a second outer portion on a side surface of the second line portion facing the third bit line, and a third outer portion extending from the first outer portion and the second outer portion, and
the third outer portion covers a side surface of the insulating pattern positioned in a direction toward the memory cell array region.

7. The semiconductor device of claim 6, further comprising:
a first inner spacer, wherein
the first inner spacer includes a first inner portion between the first line portion and the first outer portion, a second inner portion between the second line portion and the second outer portion, a third inner portion extending from the first inner portion, and a fourth inner portion extending from the second inner portion,
a portion of the third inner portion is between the insulating pattern and the first pad portion, and
a portion of the fourth inner portion is between the insulating pattern and the second pad portion.

8. The semiconductor device of claim 7, wherein a thickness of the first outer spacer is greater than a thickness of the first inner spacer.

9. The semiconductor device of claim 7, further comprising:
a first intermediate spacer, wherein
the first intermediate spacer includes a first intermediate portion between the first inner portion and the first outer portion, a second intermediate portion between the second inner portion and the second outer portion, and a third intermediate portion extending from the first intermediate portion and the second intermediate portion, and
the third intermediate portion is between the insulating pattern and the third outer portion.

10. The semiconductor device of claim 6, further comprising:
a second outer spacer covering the first end portion of the third bit line while covering both side surfaces of the third bit line,
wherein the second outer spacer is spaced apart from the first outer spacer.

11. The semiconductor device of claim 1, wherein a length of the first pad portion in the first direction and a length of second pad portion in the first direction each are two or more times greater than each of a length of the first connection portion in the first direction and a length of the second connection portion in the first direction.

12. The semiconductor device of claim 1, wherein a distance between the memory cell array region and the first connection portion is greater than a distance between the memory cell array region and the first end portion of the third bit line.

13. The semiconductor device of claim 1, wherein a distance between the memory cell array region and the first connection portion is equal to a distance between the memory cell array region and the first end portion of the third bit line.

14. A semiconductor device comprising:
a structure including a first extension region and a memory cell array region, the first extension region being adjacent to the memory cell array region;
a first bit line including a first line portion extending into the first extension region while crossing the memory cell array region in a first direction, a first connection portion extending from the first line portion in the first extension region, and a first pad portion extending from the first connection portion in the first extension region;
a second bit line including a second line portion extending into the first extension region while crossing the memory cell array region in the first direction, a second connection portion extending from the first line portion in the first extension region, and a second pad portion extending from the second connection portion in the first extension region;
a third bit line between the first line portion and the second line portion in the memory cell array region and the first extension region, the third bit line including a first end portion in the first extension region;
contact plugs including cell contact plugs in the memory cell array region and dummy contact plugs in the first extension region; and
an insulating pattern in the first extension region, wherein
the insulating pattern includes a first insulating portion between the first pad portion and the second pad portion,
the dummy contact plugs include a first dummy contact plug,
at least a portion of the first dummy contact plug is between the insulating pattern and the first end portion of the third bit line.

15. The semiconductor device of claim 14, wherein
the dummy contact plugs are not disposed between the first pad portion and the second pad portion,
a width of each of the first pad portion in a second direction and a width of the second pad portion in the second direction are each greater than a width of the first line portion in the second direction and a width of the second line portion in the second direction, and
the second direction is perpendicular to the first direction.

16. The semiconductor device of claim 14, further comprising:
an outer spacer, wherein
the outer spacer includes a first outer portion on a side surface of the first line portion facing the third bit line, a second outer portion on a side surface of the second line portion facing the third bit line, and a third outer portion extending from the first outer portion and the second outer portion, and
the third outer portion is between the insulating pattern and the first dummy contact plug.

17. The semiconductor device of claim 14, wherein
the dummy contact plugs further include second dummy contact plugs between the third bit line and the first line portion and between the third bit line and the second line portion.

18. A semiconductor device comprising:
a structure including a first extension region and a memory cell array region, the first extension region being adjacent to the memory cell array region;
a first bit line including a first line portion extending into the first extension region while crossing the memory cell array region in a first direction, a first connection portion extending from the first line portion in the first extension region, and a first pad portion extending from the first connection portion in the first extension region;
a second bit line including a second line portion extending into the first extension region while crossing the memory cell array region in the first direction, a second connection portion extending from the first line portion in the first extension region, and a second pad portion extending from the second connection portion in the first extension region;
a third bit line between the first line portion and the second line portion in the memory cell array region and the first extension region, the third bit line including a first end portion in the first extension region;
contact plugs including cell contact plugs in the memory cell array region and dummy contact plugs in the first extension region;
an insulating pattern in the first extension region; and
an outer spacer in the memory cell array region and the first extension region, wherein
the insulating pattern includes a first insulating portion between the first pad portion and the second pad portion,
the outer spacer includes a first outer portion on a side surface of the first line portion facing the third bit line, a second outer portion on a side surface of the second line portion facing the third bit line, and a third outer portion extending from the first outer portion and the second outer portion,
the third outer portion covers a side surface of the insulating pattern positioned in a direction toward the memory cell array region.

19. The semiconductor device of claim 18, further comprising:
a gate structure in a gate trench in the memory cell array region, the gate trench crossing active regions and a cell isolation region in the memory cell array region, the cell isolation region on side surfaces of the active regions in the memory cell array region;
contact plugs;
bit line contact structures; and
a data storage structure, wherein
the first extension region includes a peripheral isolation region,
the first bit line, the second bit line, and the third bit line are at a higher level than the gate structure,
the first bit line, the second bit line, and the third bit line are electrically connected to first source/drain regions of the active regions,
the contact plugs include cell contact plugs in the memory cell array region and dummy contact plugs in the first extension region,
the cell contact plugs are electrically connected to second source/drain regions of the active regions,
the dummy contact plugs are on the peripheral isolation region,
the dummy contact plugs are electrically isolated,
the bit line contact structures are on the first pad portion and the second pad portion,
the bit line contact structures are electrically connected to the first pad portion and the second pad portion, and
the data storage structure is electrically connected to the cell contact plugs.

20. The semiconductor device of claim 19, further comprising:
a first inner spacer, wherein
the first inner spacer includes a first inner portion between the first line portion and the first outer portion, a second inner portion between the second line portion and the second outer portion, a third inner portion extending from the first inner portion, and a fourth inner portion extending from the second inner portion, and a lower portion covering a lower surface of the insulating pattern,
a portion of the third inner portion is between the insulating pattern and the first pad portion,
a portion of the fourth inner portion is between the insulating pattern and the second pad portion, and
the dummy contact plugs include a first dummy contact plug and second dummy contact plugs,
at least a portion of the first dummy contact plug is between the first end portion of the third bit line and the insulating pattern,
the second dummy contact plugs are between the third bit line and the first line portion, and between the third bit line and the second line portion,
at least a portion of the third outer portion of the outer spacer is between the insulating pattern and the first end portion of the third bit line, and
the insulating pattern further includes an extension insulating portion extending from the first insulating portion in a direction away from the memory cell array region.
